(19) United States
(12) Patent Application Publication
(10) Pub. No.: US 2006/0113905 A1
(43) Pub. Date: Jun. 1, 2006

(54) Display device

(76) Inventor: Norio Nakamura, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/266,309

(22) Filed: Nov. 4, 2005

(30) Foreign Application Priority Data
Nov. 26, 2004 (JP) 2004-342560

(51) Int. Cl. H05B 33/06; H05B 33/08

(52) U.S. Cl. 313/511; 313/512

(57) ABSTRACT

A display device includes a display panel having a self-luminous display element on a substrate and having one major surface as a display surface, a driving circuit board that is connected to the display panel via a flexible board, is disposed on a non-display-surface-side of the display panel, and supplies a driving signal to the display panel, and a heat resistance layer that is disposed between the display panel and the driving circuit board.

### CROSS-REFERENCE TO RELATED APPLICATIONS

This application is based upon and claims the benefit of priority from prior Japanese Patent Application No. 2004-342560, filed Nov. 26, 2004, the entire contents of which are incorporated herein by reference.

### BACKGROUND OF THE INVENTION

1. Field of the Invention

The present invention relates generally to a display device, and more particularly to a display device that is composed of self-luminous display elements.

2. Description of the Related Art

In recent years, organic electroluminescence (EL) display devices have attracted attention as flat-panel display devices. The organic EL display device comprises self-luminous elements. Thus, it has such features as a wide viewing angle, small thickness without a need for backlight, low power consumption, and a high responsivity speed.

For these features, attention has been paid to the organic EL display device as a promising candidate for the next-generation flat-panel display device that is to replace the liquid crystal display devices. The organic EL display device comprises a display panel, a driving circuit board, a flexible wiring board, and a frame. The display panel is configured such that organic EL elements are arranged in a matrix on an array substrate. Each organic EL device has such a structure that an organic active layer including an organic compound with a light-emitting function is held between an anode and a cathode. The driving circuit board drives the display panel. The flexible wiring board transmits signals from the driving circuit board to the display panel. The frame integrally holds the display panel and the driving circuit board. There is known a structure wherein the flexible wiring board is bent along the side surface of the frame, and disposed on a non-display surface side of the display panel (see Jpn. Pat. Appln. KOKAI Publication No. 2003-100442, for instance).

In the case where the driving circuit board is fixed in close contact with the display panel, as described above, there is a fear that the temperature of the display panel rises due to radiation heat from the driving circuit and the lifetime of the self-luminous elements becomes shorter.

### BRIEF SUMMARY OF THE INVENTION

The object of the invention is to provide a display device, which can suppress degradation of self-luminous display elements and can realize a high display quality and a long lifetime.

According to an aspect of the present invention, there is provided a display device comprising: a display panel having a self-luminous display element on a substrate and having one major surface as a display surface; a driving circuit board that is connected to the display panel via a flexible board, is disposed on a non-display-surface-side of the display panel, and supplies a driving signal to the display panel; and a heat resistance layer that is disposed between the display panel and the driving circuit board.

The present invention can provide a display device, which can suppress degradation of self-luminous display elements and can realize a high display quality and a long lifetime.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 schematically shows the structure of an organic EL display device according to an embodiment of the present invention;

FIG. 2 is a cross-sectional view that schematically shows the structure of one pixel of the organic EL display device shown in FIG. 1;

FIG. 3 is a plan view that schematically shows a display panel and a driving circuit board, which are held on a frame;

FIG. 4 is a cross-sectional view of the organic EL display device, which is taken along line III-III in FIG. 3;

FIG. 5 is a cross-sectional view that schematically shows the structure of an organic EL display device including another example of a heat resistance layer; and

FIG. 6 is a cross-sectional view that schematically shows the structure of an organic EL display device including still another example of the heat resistance layer.

### DETAILED DESCRIPTION OF THE INVENTION

A display device according to an embodiment of the present invention will now be described with reference to the accompanying drawings. In this embodiment, a self-luminous display device, such as an organic EL (electroluminescence) display device, is described as an example of the display device.

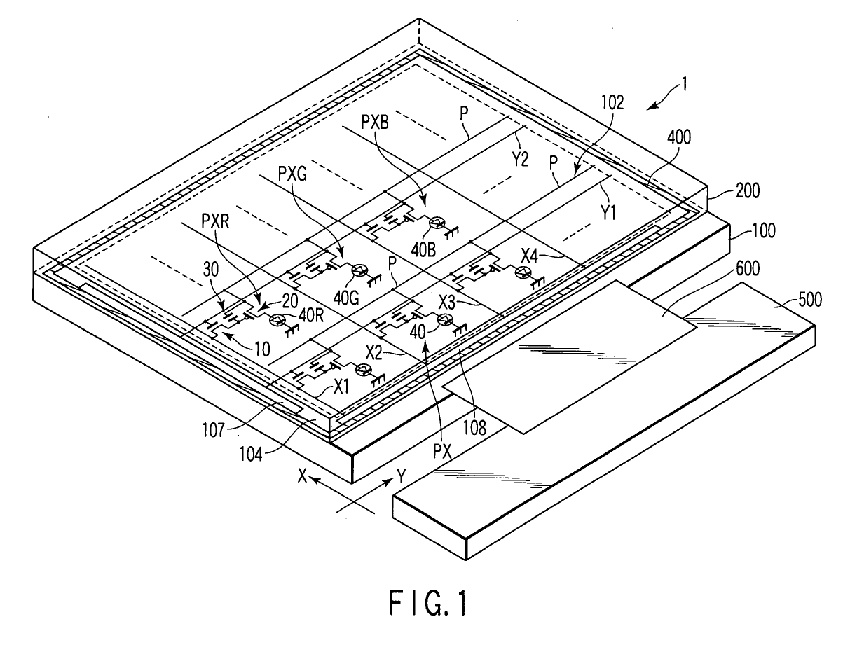

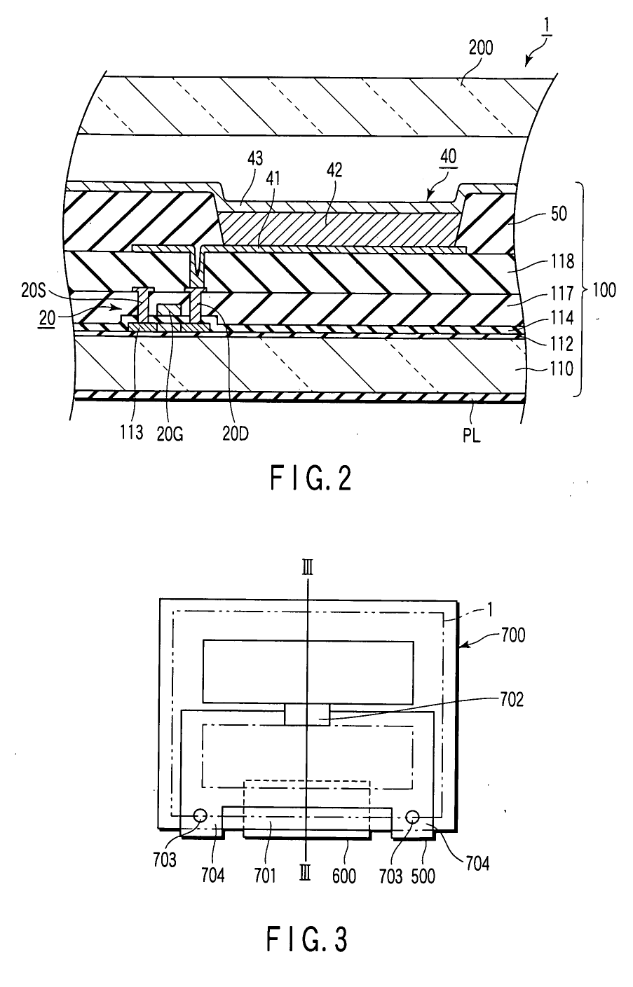

As is shown in FIG. 1 and FIG. 2, an organic EL display device includes a display panel 1 and a driving circuit board 500. The display panel 1 includes an array substrate 100 with a display area 102 for displaying an image, and a sealing member 200 that seals at least the display area 102 of the array substrate 100.

The sealing member 200 is an insulting substrate such as a glass substrate. The array substrate 100 and sealing member 200 are coupled at peripheral parts by, e.g. an adhesive or a frit seal. Thereby, an airtight space is defined therebetween. The airtight space is filled with an inert gas such as nitrogen gas, or it is evacuated. A polarizer plate PL for suppressing reflection of ambient light may be provided on an outermost surface of the display side of the display panel 1. The example shown in FIG. 2 is of a back-surface-emission type, wherein a display surface, that is, a light emission surface, is provided on the bottom side (support substrate 110) of the array substrate 100. A polarizer plate PL is provided on the outer surface of the support substrate 110. In a front-surface-emission type display panel wherein the display surface is provided on the sealing member 200 side, a polarizer plate PL is provided on the outer surface of the sealing member 200. In short, the polarizer plate PL is disposed on the display surface side of the display panel.

The array substrate 100 includes the insulating support substrate 110 that is, e.g. a glass substrate. On the support substrate 110, the display area 102 is composed of a plurality of pixels PX (R, G, B) that are arranged in a matrix.

Each pixel PX (R, G, B) comprises a pixel switch 10 having a function of electrically separating an ON pixel and an OFF pixel and holding a video signal to the ON pixel; a driving transistor 20 that supplies a desired driving current to a display element on the basis of the video signal that is supplied via the pixel switch 10; a storage capacitance element 30 that holds a gate-source potential of the driving transistor 20 for a predetermined time period; and an organic EL element 40 (R, G, B) functioning as a self-luminous display element.

The gate electrode of the pixel switch 10 is connected to a scan line Ym (m=1, 2, . . . ), the source electrode of the pixel switch 10 is connected to a signal line Xn (n=1, 2, . . . ), and the drain electrode of the pixel switch 10 is connected to one end of the storage capacitance element 30 and to a gate electrode 20G of the driving transistor 20. A source electrode 20S of the driving transistor 20 is connected to the other end of the storage capacitance element 30 and to a power supply line P. A drain electrode 20D of the driving transistor 20 is connected to the organic EL element 40.

A red pixel PXR includes an organic EL element 40R that principally emits light of a red wavelength. A green pixel PXG includes an organic EL element 40G that principally emits light of a green wavelength. A blue pixel PXB includes an organic EL element 40B that principally emits light of a blue wavelength.

As is shown in FIG. 2, a silicon nitride (SiNx) layer and a silicon oxide (SiOx) layer, for instance, are successively stacked on the support substrate 110 as an undercoat layer 112. On the undercoat layer 112, for example, a semiconductor layer 113 that is a polysilicon layer in which a channel, a source and a drain are formed, a gate insulation film 114 that is formed using, e.g. TEOS (Tetra Ethyl Ortho Silicate), and a gate electrode 20G that is formed using, e.g. molybdenum-tungsten (MoW), are successively stacked. These layers constitute a top-gate type thin-film transistor (TFT). In this example, this TFT is used as the pixel switch 10, driving transistor 20, etc. In addition, a scan line Ym, which can be formed in the same fabrication step as the gate electrode 15, is disposed on the gate insulation film 114.

The gate insulation film 114 and gate electrode 20G are coated with an interlayer insulation film 117 that is formed of, e.g. silicon oxide (SiOx) by means of, e.g. plasma CVD. A source electrode 20S and a drain electrode 20G are disposed on the interlayer insulation film 117. The source electrode 20S and drain electrode 20G are coated with a passivation film 118 that is formed of, e.g. silicon nitride (SiNx). The source electrode 20S and drain electrode 20D have a three-layer structure of, e.g. Mo/Al/Mo. The source electrode 20S and drain electrode 20D are electrically connected to the source and drain of the TFT via contact holes that are formed in the gate insulation film 114 and interlayer insulation film 117. In addition, a signal line Xn, which can be formed in the same fabrication step as the source electrode 20S and drain electrode 20D, is also disposed on the interlayer insulation film 117.

The organic EL elements 40 (R, G, B) disposed in the respective pixels PX (R, G, B) have basically the same structure. The organic EL element 40 comprises a first electrode 41 that is formed in an insular shape in each pixel PX, a second electrode 43 that is formed common to all the pixels PX and is disposed to be opposed to the first electrode 41, and an organic active layer 42 that is held between the first electrode 41 and the second electrode 43.

Specifically, the first electrode 41 is disposed on the passivation film 118. The respective first electrodes 41 are isolated from each other. Each first electrode 41 is electrically connected to the drain electrode 20D of the driving transistor 20 via a through-hole that is formed in the passivation film 118. In the back-surface-emission type device of this example, the first electrode 41 is formed of a light-transmissive, electrically conductive material such as ITO (Indium Tin Oxide) or IZO (Indium Zinc Oxide), and the first electrode 41 functions as an anode.

The organic active layer 42 includes a light-emitting layer. The organic active layer 42 may include layers other than the light-emitting layer. For example, the organic active layer 42 may have a two-layer structure comprising a hole transporting layer that is common to the respective colors and a light-emitting layer that is formed for each color pixel. Alternatively, the organic active layer 42 may include a hole transporting layer, a blocking layer, an electron transporting layer, an electron injection layer, and a buffer layer, or the organic active layer 42 may include a layer in which the functions of these layers are integrated. In the organic active layer 42, it is necessary that only the light-emitting layer be formed of an organic material. The layers other than the light-emitting layer may be formed of either an inorganic material or an organic material. The light-emitting layer is formed of an organic compound having a light-emitting function of emitting red, green or blue light.

The second electrode 43 is disposed on the organic active layer 42 commonly to all the organic EL elements 40. The second electrode 43 is formed of a metallic film with an electron injection function such as Ca (calcium), Al (aluminum), Ba (barium), Ag (silver) or Yb (ytterbium), and functions as a cathode. The second electrode 43 may be a two-layer structure in which the surface of a metal film functioning as a cathode is coated with a cover metal. The cover metal is formed of, e.g. aluminum.

The array substrate 100 includes partition walls 50 that separate the pixels RX (R, G, B) in the display area 102. The partition walls 70 are arranged in a lattice shape or in stripes along the peripheral edges of the first electrodes 41 on the passivation film 118. The partition walls 50 are, for example, organic insulating layers and can be formed by photolithography.

The array substrate 100 further includes, in its peripheral area 104 that is provided around the outer periphery of the display area 102, at least a part of a scan line driving circuit 107, which supplies scan signals to the scan lines Ym, and at least a part of a signal line driving circuit 108, which supplies video signals to the signal lines Xn. All scan lines Ym are connected to the scan line driving circuit 107. All signal lines Xn are connected to the signal line driving circuit 108.

The driving circuit board 500 supplies driving signals to the display panel 1. The driving circuit board 500 is equipped with, for example, circuits for controlling the scan line driving circuit 107 and signal line driving circuit 108, and circuits such as a power supply circuit. The driving circuit board 500 is connected to the array substrate 100 of the display panel 1 via a flexible board 600.

As is shown in FIG. 3 and FIG. 4, the driving circuit board 500 is disposed on the display panel 1 by bending flexible board 600, with a heat resistance layer being interposed. The heat resistance layer is an air layer, and the driving circuit board 500 is disposed such that the driving circuit board 500 is opposed to the display panel 1 with a gap G provided therebetween. Specifically, in the organic EL display device in which an area light source unit such as a backlight unit is needless, the driving circuit board 500 can be disposed on the side opposite to the display surface of the display panel 1. Thereby, the picture-frame-like part of the display device can be reduced in size, and the dimensions of the entire display device can be reduced. However, the driving circuit board 500 includes a circuit with a relatively large heat production amount, such as a power supply circuit. If the driving circuit board 500 is fixed in close contact with the display panel 1, radiation heat from the circuit raises the temperature of the display panel 1. The rising of the temperature of the display panel 1 would possibly degrade the display elements and the lifetime of the product would become shorter.

If the driving circuit board 500 is fixed such that the board 500 is spaced apart from the display panel 1, as described above, the effect of radiation heat from the driving circuit board 500 can be minimized.

Specifically, as shown in FIG. 3 and FIG. 4, the organic EL display device includes a frame 700 that holds the display panel 1 and driving circuit board 500. The display panel 1 is fixed to the frame 700 via an adhesive tape 800, and a bezel 900 holds the display panel 1 to the frame 700.

The frame 700 has a rectangular frame-like shape with dimensions substantially equal to those of the display panel 1. The frame 700 includes an intervening portion 701 that intervenes between the display panel 1 and driving circuit board 500 when the driving circuit board 500 is disposed to be opposed to the display panel 1; a claw portion 702 that engages the driving circuit board 500; and screw-coupling portions 704 that fix the driving circuit board 500 by means of screws 703.

In the example shown in FIG. 4, the driving circuit board 500 is disposed to be opposed to the sealing member 200 of the display panel 1. It should suffice if the intervening portion 701 extends over at least a part of the region between the sealing member 200 and the driving circuit board 500. By virtue of the intervening portion 701, the driving circuit board 500 is prevented from contacting the display panel 1 and is fixed to the frame 700 in the state in which the gap G corresponding to the thickness of the intervening portion 701 is provided. At this time, the heat resistance layer that is provided between the display panel 1 and driving circuit board 500 is an air layer with a relatively high heat resistance (coefficient of thermal conductivity: about 0.02 (W/m·k)), which can suppress the effect of radiation heat from the driving circuit board 500.

It should suffice if the heat resistance layer is formed of a material with a relatively low coefficient of thermal conductivity. In the case where the frame 700 is formed of a resin material with a relatively low coefficient of thermal conductivity, such as polycarbonate (coefficient of thermal conductivity: about 0.2 (W/m·k)), a heat resistance layer may be formed between the display panel 1 and driving circuit board 500 by disposing the intervening portion 701 over the entire region between the display panel 1 and driving circuit board 500. Alternatively, a heat resistance layer may be formed between the display panel 1 and driving circuit board 500 by disposing a columnar member between the display panel 1 and driving circuit board 500.

In this case, the thickness of the heat resistance layer corresponds to a height in a direction normal to the major surface of the display panel 1, and should preferably be 0.1 mm or more and 1.0 mm or less. In other words, by securing a minimum distance of 0.1 mm or more between the display 1 and the driving circuit board 500 (i.e. distance between the display panel and the circuit on the driving circuit board), the effect of radiation heat from the driving circuit board 500 can be suppressed. In the case of a single-side mounting structure wherein various circuits are mounted only on a surface of the driving circuit board 500, which is opposed to the display panel 1, if a gap G of about 0.1 mm is provided between the display panel 1 and driving circuit board 500, a minimum distance of about 0.1 mm can be secured between the display panel 1 and driving circuit board 500. In addition, as the gap G becomes greater, the effect of heat can be reduced. However, if the gap G is excessively increased, the thickness of the display device would increase and the reduction in size cannot be achieved. In the case of a double-side mounting structure wherein various circuits are mounted on both side surfaces of the driving circuit board 500, if a gap G of about 1.0 mm is provided between the display panel 1 and driving circuit board 500 in consideration of the thickness of the circuits mounted on the driving circuit board 500, a minimum distance of about 0.1 mm or more can substantially be secured between the display panel 1 and driving circuit board 500, and the effect of radiation heat from the driving circuit board 500 can be suppressed.

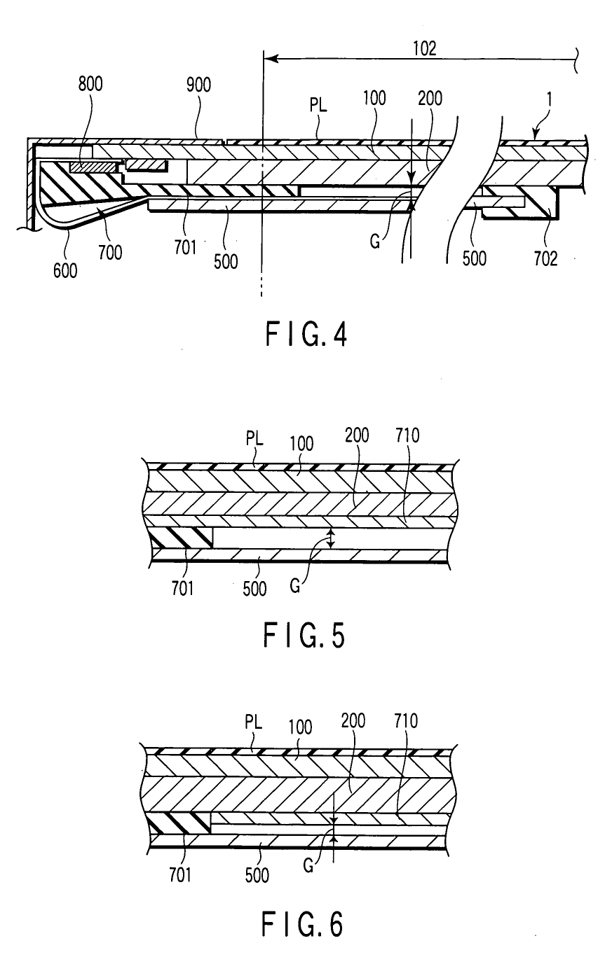

The organic EL display device may further include a metal sheet 710. For example, as shown in FIG. 5, a heat diffusion sheet 710, which is formed of a metal such as aluminum or copper, or graphite, may be disposed between the sealing member 200 and the frame 700 over the entire surface of the sealing member 200. Alternatively, as shown in FIG. 6, a heat diffusion sheet 710 may be disposed over the entire surface of the heat resistance layer.

### EXAMPLE

In an organic EL display device with the above-described structure, a gap G of 0.1 mm was provided between the display panel 1 and the driving circuit board 500 having the single-side mounting structure. As regards this structure, the temperature of the display panel 1 before turn-on of power was compared with the temperature of the display panel 1 in the state in which a variation in temperature was stabilized after turn-on of power. The temperature of the display panel 1 rose by 5° C.

### COMPARATIVE EXAMPLE

In an organic EL display device with the above-described structure, the display 1 and driving circuit board 500 were disposed in close contact with each other (gap G=0 mm). As regards this structure, the temperature of the display panel 1 before turn-on of power was compared with the temperature of the display panel 1 in the state in which a variation in temperature was stabilized after turn-on of power. The temperature of the display panel 1 rose by 10° C.

In the above-described Example, the gap G of at least 0.1 mm was provided between the display panel 1 and the driving circuit board 500. Thereby, the increase in temperature of the display panel was successfully reduced, compared to the case where the display 1 and driving circuit board 500 were disposed in close contact with each other.

As has been described above, the driving circuit board, which is connected to the display panel via the flexible board, is disposed to be opposed to the display panel by bending the flexible board, with a gap being provided between the driving circuit board and the display panel. Thus, radiation heat from the driving circuit board is not easily conducted to the display panel, and it is possible to prevent degradation of the display elements, which are disposed on the display panel, due to the effect of heat. Accordingly, the initial display quality at the beginning of use can be maintained for a long time. Therefore, a display device, which can realize a high display quality and a long lifetime, can be provided.

The present invention is not limited to the above-described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

For example, in the case of a front-surface-emission type organic EL display device, the driving circuit board 500 may be disposed to be opposed to the array substrate 100, with a gap being provided therebetween. In this case, a polarizer plate may be disposed on the outer surface of the sealing member 200.

What is claimed is:

1. A display device comprising:
a display panel having a self-luminous display element on a substrate and having one major surface as a display surface;
a driving circuit board that is connected to the display panel via a flexible board, is disposed on a non-display-surface-side of the display panel, and supplies a driving signal to the display panel; and
a heat resistance layer that is disposed between the display panel and the driving circuit board.

2. The display device according to claim 1, wherein the heat resistance layer has a thickness of 0.1 mm or more and 1.0 mm or less.

3. The display device according to claim 1, wherein the heat resistance layer is an air layer.

4. The display device according to claim 1, further comprising a frame that holds the display panel and the driving circuit board,
wherein a thickness of the heat resistance layer is defined by the frame.

5. The display device according to claim 1, wherein the display element includes:
a first electrode that is formed on the substrate on a pixel-by-pixel basis;
a second electrode that is disposed to be opposed to the first electrode and is formed common to all pixels; and
an organic active layer that is held between the first electrode and the second electrode.
